(19) United States
(12) Patent Application Publication
(10) Pub. No.: US 2021/0296858 A1
(43) Pub. Date: Sep. 23, 2021

(54) LASER BEAM COMBINING DEVICE WITH AN UNSTABLE RESONATOR CAVITY

(71) Applicant: II-VI Suwtech, Inc., Shanghai (CN)

(72) Inventors: Quan ZHOU, Shanghai (CN); Dashan LI, Shanghai (CN); Yaping ZHAO, Shanghai (CN); Pingping YE, Shanghai (CN)

(73) Assignee: II-VI Suwtech, Inc., Shanghai (CN)

(21) Appl. No.: 17/266,128

(22) PCT Filed: Sep. 9, 2019
(86) PCT No.: PCT/CN2019/104900

§ 371 Date: Feb. 5, 2021

(30) Foreign Application Priority Data
Sep. 13, 2018 (CN) 201821499209.7

(51) Int. Cl. H01S 5/10; H01S 3/081; H01S 5/40; H01S 5/14; H01S 5/028

(52) U.S. Cl. CPC H01S 5/1089; H01S 3/0818; H01S 5/0287; H01S 5/143; H01S 5/4062

(57) ABSTRACT

A laser beam combining device with an unstable resonator cavity includes a semiconductor laser source configured to emit a plurality of laser beams to a beam shaper to form a plurality of parallel laser beams and the parallel laser beams are focused, by a transform lens, to a diffraction grating, wherein the diffraction grating diffracts the focused laser beams to form a combined laser beam, wherein the transform lens is disposed between the semiconductor laser source and the diffraction grating and an output coupler including a cylindrical surface with partial reflection coating, wherein a portion of the combined laser beams is oscillated between the cylindrical surface and the back facet of the semiconductor laser, and the portion of the combined laser beams is emitted via the output coupler.

### CROSS REFERENCE

This application is based upon PCT patent application No. PCT/CN2019/104900 filed on Sep. 9, 2019, which claims priority to Chinese Patent Application No. 201821499209.7, filed on Sep. 13, 2018, the entire contents of which are incorporated herein by reference.

### TECHNICAL FIELD

The present disclosure relates to the field of a semiconductor laser field, specifically to a laser beam combining device with an unstable resonator cavity.

### BACKGROUND

Semiconductor lasers have the advantages of low cost, long life, small size, high reliability, etc., and have broad application prospects in industrial processing, pumping, medical, communication, etc. Whether the brightness of semiconductor lasers can be further improved is an important factor that restricts the future development of semiconductor lasers. The brightness of the laser beam is determined by the magnitude of the output power and the beam quality.

The beam combining technique is currently a common means of implementing high-brightness semiconductor lasers. The beam combining technique includes beam shaping, polarization combining, wavelength combining, etc. Beam shaping improves the beam quality by balancing the beam parameter products in the direction of the fast and slow axis. The polarization beam combining combines the beams of two polarization directions into one beam, and the brightness is and the brightness then only doubled. Moreover, the wavelength combination is restricted due to the limitation of coating technology. The number of combining units is generally not more than five, and the improvement in power and brightness is also limited.

Spectral beam combining is a novel technology in semiconductor laser beam combination. The laser emitters are locked at different wavelengths by external cavity feedback and the dispersion of the grating. Thus, the different laser beams are able to diffract at a same angle after the grating to achieve the combination. The advantages of spectral beam combining are as the followings: Firstly, spectral beam combining provide a solution to combine beams from all the laser emitters while maintaining the beam quality of a single laser emitter, which greatly improves the brightness of the semiconductor laser. Secondly, all the laser emitters share the same combined component and the number of combined laser emitters is not limited, the cost is greatly reduced due to the feature of the unlimited number of the combined elements. Therefore, spectral beam combining technology has become an important research area of high power semiconductor lasers.

The current spectral beam combining uses a plane mirror as an output coupler. The external cavity is a plane-plane cavity, which is a stable cavity. The crosstalk is easily caused in the stable cavity and the beam quality get worse.

### SUMMARY

In view of this, an objective of the present disclosure is to provide a laser beam combining device with an unstable resonator cavity to solve problems of poor beam quality of the stable cavity laser in the prior art.

In one embodiment of the present disclosure, a laser beam combining device with an unstable resonator cavity includes a semiconductor laser source configured to emit a plurality of laser beams to a beam shaper to form a plurality of parallel laser beams and the parallel laser beams are focused, by a transform lens, to a diffraction grating. The diffraction grating diffracts the focused laser beams to form a combined laser beam. The transform lens is disposed between the semiconductor laser source and the diffraction grating. An output coupler includes a cylindrical surface with partial reflection coating and a portion of the combined laser beams is oscillated between the cylindrical surface and the back facet of the semiconductor laser. The portion of the combined laser beams is emitted via the output coupler.

In one embodiment of the present disclosure, the output coupler includes a cylindrical plano-convex lens including a convex surface facing the combined laser beam.

In one embodiment of the present disclosure, the convex surface of the cylindrical plano-convex lens is partial reflection coated and the flat surface of the cylindrical piano-convex lens is anti-reflection coated.

In one embodiment of the present disclosure, a reflection rate of the partial reflection film is in a range of 5% to 30% and/or a transmission rate of the anti-reflection film is greater than 99%.

In one embodiment of the present disclosure, the output coupler includes a cylindrical plano-concave lens including a flat surface facing the combined laser beam.

In one embodiment of the present disclosure, the concave surface of the cylindrical plano-concave lens is partial reflection coated and the flat surface of the cylindrical plano-convex lens is anti-reflection coated.

In one embodiment of the present disclosure, a reflection rate of the partial reflection film is in a range of 5% to 30% and/or a transmission rate of the anti-reflection film is greater than 99%.

In one embodiment of the present disclosure, the semiconductor laser source includes a front facet coated with an anti-reflection film and a back facet coated with a highly reflective film.

In one embodiment of the present disclosure, reflection rate of the anti-reflection film is smaller than 10% and/or a reflection rate of the highly reflective film is greater than 95%.

In one embodiment of the present disclosure, the diffraction grating includes a transmission grating, wherein the diffraction efficiency of the diffraction grating is greater than 90% at 1st order.

In one embodiment of the present disclosure, the diffraction grating includes a transmission grating, wherein the diffraction efficiency of the diffraction grating is greater than 900% at −1st order.

In one embodiment of the present disclosure, the diffraction grating includes a reflection grating, wherein the diffraction efficiency of the diffraction grating is greater than 90% at 1st order.

In one embodiment of the present disclosure, the diffraction grating includes a reflection grating, wherein the diffraction efficiency of the diffraction grating is greater than 90° % at −1st order.

In one embodiment of the present disclosure, the transform lens includes one of a spherical cylindrical lens, a lens set including a plurality of spherical cylindrical lenses, an aspheric cylindrical lens, and a lens set including a plurality of aspheric cylindrical lenses.

In one embodiment of the present disclosure, the beam shaper includes one of a fast-axis collimator (FAC) lens, a lens set including a FAC lens and a slow-axis collimator (SAC) lens and a lens set including a FAC lens and a beam twister.

In one embodiment of the present disclosure, the semiconductor laser source includes one of a semiconductor laser array including a plurality of laser emitting units, a plurality of semiconductor laser diode, and a two-dimensional semiconductor laser array.

In order to further understand the features and technical contents of the present disclosure please refer to the following detailed description and drawings related to the present disclosure. However, the detailed description and the drawings are merely illustrative of the disclosure and are not intended to limit the scope of the claims.

### BRIEF DESCRIPTION OF THE DRAWINGS

Embodiments of the present disclosure will now be described, by way of example only, with reference to the accompanying schematic drawings in which corresponding reference symbols indicate corresponding parts, and in which:

FIG. 1 shows a schematic view of a laser beam combining device with an unstable resonator cavity of one embodiment of the present disclosure;

FIG. 2 shows a schematic view of crosstalk eliminations of the laser beam combining device with an unstable resonator cavity of FIG. 1; and

FIG. 3 shows a schematic view of another laser beam combining device with an unstable resonator cavity of one embodiment of the present disclosure.

### DETAILED DESCRIPTION

In the following, embodiments of the present disclosure will be described in detail referring to figures. The concept and its realizations of the present disclosure can be implemented in a plurality of forms, and should not be understood to be limited to the embodiments described hereafter. In contrary, these embodiments are provided to make the present disclosure more comprehensive and understandable, so the conception of the embodiments can be conveyed to the technicians in the art fully. Same reference signs in the figures refer to same or similar structures, so repeated description of them will be omitted.

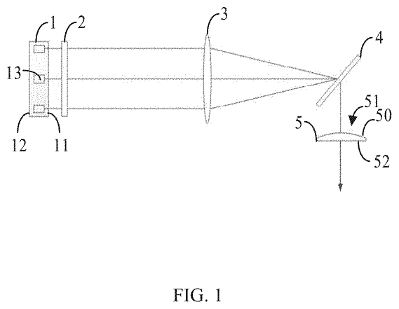

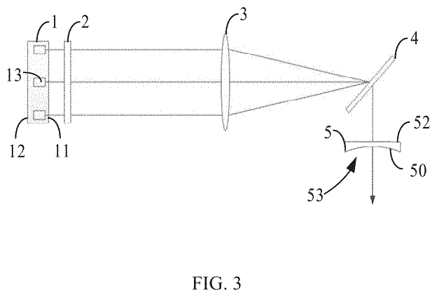

FIG. 1 shows a schematic view of a laser beam combining device with an unstable resonator cavity of one embodiment of the present disclosure. FIG. 3 shows a schematic view of another laser beam combining device with an unstable resonator cavity of one embodiment of the present disclosure. As shown in FIGS. 1 and 3, in the embodiments of the present disclosure, the laser beam combining device with an unstable resonator cavity includes a semiconductor laser source 1, a beam shaper 2, a transform lens 3 and a diffraction grating 4 which are sequentially and horizontally arranged. The semiconductor laser source 1 includes a laser beam emitting array. The laser beam emitting array includes a plurality of laser beam emitting modules 13, as shown in FIGS. 1 and 3, vertically arranged and emitting a plurality of collimated laser beams in parallel. The beam shaper 2 is configured to shape the laser beams emitted by the laser beam emitting array. In some embodiments, the beam shaper 2 includes at least one optical element for shaping received laser beams emitted by the semiconductor laser source 1. The transform lens 3 is disposed in the laser beam emitting direction of the semiconductor laser source 1 and a focal length of the transform lens 3 is equal to a length between the transform lens 3 and the semiconductor laser beams 1, which means the semiconductor laser source 1 is disposed on the front focal plane of the transform lens 3. In this embodiment, the transform lens 3 is configured to re-collimate the shaped, by the beam shaper 2, laser beams, generated by the semiconductor laser source 1, and focus the laser beams to a diffraction grating 4.

The diffraction grating 4 is disposed on the rear focal plane of the transform lens 3. The diffraction grating 4 is configured to diffract the focused laser beams to form a combined laser beam, wherein the focused laser beams are focused by the transform lens 3.

An output coupler 5 is disposed in the laser beam emitting direction of the diffraction grating 4. In some embodiments, the output coupler 5 includes an output couple lens. The output coupler 5 includes a cylinder 50 having a partially reflective arc plane. The partially reflective arc plane of the cylinder 50 is facing the combined laser beam emitted by the diffraction grating 4. In this embodiment, the combined laser beam, as shown in FIG. 1, is emitted by the diffraction grating 4 and vertically reached the reflective arc plane of the cylinder 50. Therefore, an unstable resonator cavity is then formed between the cylinder 50 and the semiconductor laser source 1. A portion of the combined laser beam is oscillated between the cylinder 50 and the semiconductor laser source 1.

Since the unstable resonator cavity is formed between the cylinder 50 and the semiconductor laser source 1, low order mode laser beams of the combined laser beams are oscillated between the cylinder 50 and the semiconductor laser source 1, and amplified by a gain media (not shown) to form a laser beam with high beam quality.

In some embodiments, the parallel laser beams, emitted by the semiconductor laser, are shaped by the beam shaper 2. The shaped beams are then collimated and focused, by the transform lens 3, to the diffraction grating 4. The diffraction grating 4 is configured to diffract the received laser beams to form a combined laser beam. The combined laser beam is then outputted to the cylinder 50 of the output coupler 5. Moreover, the portion of the combined laser beam is reflected, by the cylinder 50, back to the diffraction grating 4. Furthermore, a portion of the reflected laser beam is transmitted, by the diffraction grating 4, back to the semiconductor laser source 1. Therefore, in this embodiment, the laser beam is oscillated back and forward between the semiconductor laser source 1 and the cylinder 50 of the output coupler 5. During the process of the back and forward oscillating, the low order mode laser beams are then amplified to generate the laser beam with high beam quality. As shown in FIG. 1, a laser beam outputted by the output coupler 5 is a low order mode laser beam with high beam quality which is generated by oscillation process.

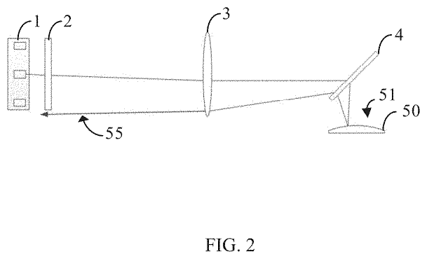

Moreover, high order mode laser beams are loss in the oscillation process. In the oscillation process, as shown in FIG. 2, after the high order laser beams are reflected by the cylinder 50, the reflected high order mode laser beams are diffracted, by the diffraction grating 4, without reaching the beam shaper 2. In some embodiments, as shown in FIG. 2, the reflected high order mode laser beams 55 are reflected and deviated as shown in FIG. 2. The deviated high order mode laser beams are no longer to return the semiconductor laser source 1. Therefore, in this embodiment, the high order mode laser beams are loss in the oscillation process. The loss of the high order mode laser beams, caused in the oscillation process, is increased due to the unstable resonator cavity formed between the cylinder 50 and the semiconductor laser source 1. The low order mode laser beams are then amplified to generate the laser beam with high quality.

Furthermore, in some embodiments, the output coupler 5, as shown in FIG. 1, is a plano-convex cylindrical lens and the cylinder 50 is a convex surface 51. The combined laser beams vertically reaches the convex surface 51. A flat surface 52 of the output coupler 5 is away from the diffraction grating 4. The convex surface 51 includes a partial reflection coating and the flat surface 52 includes an anti-reflection coating. In some embodiments, the reflection rate of the partial reflection coating of the convex surface 51 is in a range of 5% to 30%, and the reflection rate of the anti-reflection coating on flat surface 52 is smaller than 1%.

Moreover, the semiconductor laser source 1 includes a front facet 11 coated with an anti-reflection film and a back facet 12 coated with a highly reflective film. In this embodiment, a reflection rate of the anti-reflection coating of the front end surface 11 is smaller than 1% and a reflection rate of the high reflection coating of the back facet 12 is greater than 95%. Therefore, a plano-convex cavity is formed between the convex surface 51 of the output coupler 5 and the back facet 12 of the semiconductor laser source 1.

In some embodiments, a reflection rate of the anti-reflection coating of the front end surface 11 is smaller than 1% or a reflection rate of the high reflection coating of the back facet 12 is greater than 95%.

Moreover, the transform lens 3 includes a slow-axis cylindrical lens. When the laser beams are oscillated in the piano-convex cavity, the high order mode laser beams are loss and the low order mode laser beams are amplified. Therefore, the crosstalk in the slow-axis caused between the different laser beam emitting modules 13 is reduced and the laser beam with high quality is then generated.

In some embodiments, the output coupler 5, as shown in FIG. 3, is a plano-concave cylindrical lens and the cylinder 50 is a concave surface 53. The combined laser beams vertically reaches the concave surface 53. A flat surface 52 of the output coupler 5 is away from the diffraction grating 4. The concave surface 53 includes a partial reflection coating and the flat surface 52 includes an anti-reflection coating. In some embodiments, the reflection rate of the partial reflection coating of the concave surface 53 is in a range of 5% to 30%. The anti-reflection coating of the flat surface 52 is greater than 99%.

Moreover, as shown in FIG. 3, a front end surface 11 of the semiconductor laser source 1 includes an anti-reflection coating. A back facet 12 of the semiconductor laser source 1 includes a high reflection coating. In this embodiment, the reflection rate of the anti-reflection coating of the front end surface 11 is smaller than 1%. The reflection rate of the high reflection coating of the back facet 12 is greater than 95%. Therefore, a plano-convex cavity is formed between the concave surface 53 of the output coupler 5 and the back facet 12 of the semiconductor laser source 1.

Moreover, the transform lens 3 includes a slow-axis cylindrical lens. When the laser beams are oscillated in the plano-convex cavity, the high order mode laser beams are loss and the low order mode laser beams are amplified. Therefore, the crosstalk in the slow-axis caused between the different laser beam emitting modules 13 is reduced and the laser beam with high quality is then generated.

As mentioned above, the semiconductor laser source 1 includes the laser emitting modules 13 arranged as an array. The crosstalk, caused in the slow-axis, between the laser emitting modules 13 is effectively reduced by the unstable resonator cavity formed between the output coupler 5 and the semiconductor laser source 1. In some embodiments, the semiconductor source 1 includes a plurality of semiconductor laser arrays horizontally arranged. In some embodiments, the semiconductor source 1 includes a plurality of semiconductor laser arrays vertically arranged. In some embodiments, the semiconductor source 1 includes a plurality of semiconductor laser single tubes. In some embodiments, the semiconductor source 1 includes a plurality of semiconductor laser single tubes arranged in a two-dimensional array.

In some embodiments, the beam shaper 2 includes a fast-axis collimating lens. In some embodiments, the beam shaper 2 includes a combination of a fast-axis collimating lens and a slow-axis collimating lens. In some other embodiments, the beam shaper 2 includes a combination of a fast-axis collimating lens and a oblique cylindrical lens of 45°.

In some embodiments, the transform lens 3 includes a spherical cylindrical lens. In some embodiments, the transform lens 3 includes a lens set having a plurality of spherical cylindrical lens. In some embodiments, the transform lens 3 includes an aspheric cylindrical lens. In some embodiments, the transform lens 3 includes a lens set having a plurality of aspheric cylindrical lens.

The diffraction grating 4, in some embodiments, includes a transmission grating or a reflection grating. The diffraction efficiency, at 1st-order and −1st-order, of the diffraction grating 4 is greater than 90%. In some embodiments, the diffraction efficiency, at −1st-order, of the diffraction grating 4 is greater than 90%.

Thus, in the present disclosure, a laser beams combining device with an unstable resonator cavity is disclosed and is for reducing crosstalk, in the slow-axis direction, caused between a plurality of laser emitting modules 13 of a semiconductor laser beam source 1 and improving quality of the laser beams in the slow-axis direction. A plurality of parallel laser beams, emitted by the semiconductor laser source 1 and shaped by a beam shaper 2, are collimated by a transform lens 3. The collimated laser beams are further focused to a diffraction grating 4 by transform lens 3. Moreover, a combined laser beam is diffracted by the diffraction grating 4 and is oscillated in an unstable resonator cavity formed between a cylinder 50 of an output coupler 5 and the semiconductor laser source 1. In the oscillating process, a high order mode laser beam is easier to be loss in the unstable resonator cavity due to the high diffraction loss compared with the diffraction loss of a low order laser beam. Moreover, the quality of the low order laser beam is then improved after the oscillation. The improved low order laser beams are then formed an output laser beam. Therefore, in the present disclosure, the crosstalk in the axis direction caused between the different laser emitting modules is then effectively reduced and the quality of the laser beams in the low axis direction is improved. While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A laser beam combining device with an unstable resonator cavity, comprising:
a semiconductor laser source configured to emit a plurality of laser beams to a beam shaper to form a plurality of parallel laser beams and the parallel laser beams are focused, by a transform lens, to a diffraction grating, wherein the diffraction grating diffracts the focused laser beams to form a combined laser beam, wherein the transform lens is disposed between the semiconductor laser source and the diffraction grating;
an output coupler including a cylindrical surface with partial reflection coating, wherein a portion of the combined laser beams is oscillated between the cylindrical surface and the back facet of the semiconductor laser, and the portion of the combined laser beams is emitted via the output coupler.

2. The laser beam combining device of claim 1, wherein the output coupler comprises a cylindrical plano-convex lens including a convex surface facing the combined laser beam.

3. The laser beam combining device of claim 2, wherein the convex surface of the cylindrical plano-convex lens is partial reflection coated and the flat surface of the cylindrical plano-convex lens is anti-reflection coated.

4. The laser beam combining device of claim 3, wherein a reflection rate of the partial reflection film is in a range of 5% to 30% and/or a transmission rate of the anti-reflection film is greater than 99%.

5. The laser beam combining device of claim 1, wherein the output coupler comprises a cylindrical plano-concave lens including a flat surface facing the combined laser beam.

6. The laser beam combining device of claim 5, wherein the concave surface of the cylindrical plano-concave lens is partial reflection coated and the flat surface of the cylindrical plano-convex lens is anti-reflection coated.

7. The laser beam combining device of claim 6, wherein a reflection rate of the partial reflection film is in a range of 5% to 30% and/or a transmission rate of the anti-reflection film is greater than 99%.

8. The laser beam combining device of claim 1, wherein the semiconductor laser source includes a front facet coated with an anti-reflection film and a back facet coated with a highly reflective film.

9. The laser beam combining device of claim 8, wherein a reflection rate of the anti-reflection film is smaller than 1% and/or a reflection rate of the highly reflective film is greater than 95%.

10. The laser beam combining device of claim 1, wherein the diffraction grating includes a transmission grating, wherein the diffraction efficiency of the diffraction grating is greater than 90% at 1st order.

11. The laser beam combining device of claim 1, wherein the diffraction grating includes a transmission grating, wherein the diffraction efficiency of the diffraction grating is greater than 90% at −1st order.

12. The laser beam combining device of claim 1, wherein the diffraction grating includes a reflection grating, wherein the diffraction efficiency of the diffraction grating is greater than 90% at 1st order.

13. The laser beam combining device of claim 1, wherein the diffraction grating includes a reflection grating, wherein the diffraction efficiency of the diffraction grating is greater than 90% at −1st order.

14. The laser beam combining device of claim 1, wherein the transform lens includes one of a spherical cylindrical lens, a lens set including a plurality of spherical cylindrical lenses, an aspheric cylindrical lens, and a lens set including a plurality of aspheric cylindrical lenses

15. The laser beam combining device of claim 1, wherein the beam shaper includes one of a fast-axis collimator (FAC) lens, a lens set including a FAC lens and a slow-axis collimator (SAC) lens and a lens set including a FAC lens and a beam twister.

16. The laser beam combining device of claim 1, wherein the semiconductor laser source includes one of a semiconductor laser array including a plurality of laser emitting units, a plurality of semiconductor laser diode, and a two-dimensional semiconductor laser array.
